(19) United States
(12) Patent Application Publication
(10) Pub. No.: US 2025/0143100 A1
(43) Pub. Date: May 1, 2025

(54) DISPLAY DEVICE AND METHOD OF MANUFACTURING THE SAME

(71) Applicant: Samsung Display Co., LTD., Yongin-si (KR)

(72) Inventors: SANGHO LEE, Yongin-si (KR); YOOLGUK KIM, Yongin-si (KR); JIYOON KIM, Yongin-si (KR); HYEONSIK KIM, Yongin-si (KR); HEEWOON IM, Yongin-si (KR)

(73) Assignee: Samsung Display Co., LTD., Yongin-si (KR)

(21) Appl. No.: 18/922,758

(22) Filed: Oct. 22, 2024

(30) Foreign Application Priority Data
Oct. 30, 2023 (KR) 10-2023-0147240

(51) Int. Cl. H10K 59/124; H10K 59/12

(52) U.S. Cl. CPC H10K 59/124; H10K 59/1201

(57) ABSTRACT

A display device includes an inorganic insulating layer disposed on a substrate, a hydrogen supply layer disposed on the inorganic insulating layer, a pixel electrode contacting the hydrogen supply layer, and an interlayer that receives a hydrogen ion from the hydrogen supply layer and is disposed on the pixel electrode.

### CROSS-REFERENCE TO RELATED APPLICATION(S)

This application claims priority to and benefits of Korean Patent Application No. 10-2023-0147240 under 35 U.S.C. § 119, filed on Oct. 30, 2023, in the Korean Intellectual Property Office (KIPO), the entire contents of which are incorporated herein by reference.

### BACKGROUND

### 1. Technical Field

Embodiments relate to a display device that provides visual information and a method of manufacturing the same.

### 2. Description of the Related Art

As information technology develops, the importance of a display device, which is a connecting medium between users and information, is emerging. Accordingly, a use of the display device such as a liquid crystal display device, an organic light emitting display device, a plasma display device, a quantum dot light emitting display device, is increasing.

The quantum dot light emitting display device is a display device that uses quantum dots as a light emitter. The quantum dot light emitting device has the advantage of having a high chromaticity and being capable of producing multiple colors. Recently, there has been a demand for ways to improve the luminous efficiency of the quantum dot light emitting display device.

### SUMMARY

Embodiments provide a display device with improved display quality.

Embodiments provide a method of manufacturing the display device.

A display device according to an embodiment may include an inorganic insulating layer disposed on a substrate, a hydrogen supply layer disposed on the inorganic insulating layer, a pixel electrode contacting the hydrogen supply layer; and an interlayer that receives a hydrogen ion from the hydrogen supply layer and is disposed on the pixel electrode.

In an embodiment, the display device may further include an organic insulating layer disposed on the inorganic insulating layer. The hydrogen supply layer may be disposed on the organic insulating layer.

In an embodiment, an upper surface of the hydrogen supply layer may contact the pixel electrode.

In an embodiment, the hydrogen supply layer may cover an upper surface of the organic insulating layer and a side surface of the organic insulating layer.

In an embodiment, the organic insulating layer may include a first opening penetrating the organic insulating layer, and the hydrogen supply layer may include a second opening overlapping a first opening in a plan view.

In an embodiment, the hydrogen supply layer may cover the organic insulating layer in the first opening.

In an embodiment, the display device may further include an organic insulating layer disposed on the inorganic insulating layer. The hydrogen supply layer may be disposed between the inorganic insulating layer and the organic insulating layer.

In an embodiment, the hydrogen supply layer may contact each of the inorganic insulating layer and the organic insulating layer.

In an embodiment, the organic insulating layer may include a first opening, and the hydrogen supply layer may include a second opening overlapping a first opening in a plan view.

In an embodiment, a portion of the hydrogen supply layer may contact the pixel electrode through the first opening.

In an embodiment, the display device may further include a common electrode disposed on the interlayer. The interlayer may include a light-emitting layer and an electron auxiliary layer that supplies an electron to the light-emitting layer.

In an embodiment, the light-emitting layer may include a quantum dot, and the electron auxiliary layer may include a metal oxide.

In an embodiment, the electron auxiliary layer may include at least one of a zinc oxide and a zinc manganese oxide.

In an embodiment, the hydrogen supply layer may include a silicon nitride.

In an embodiment, the hydrogen supply layer may include a silicon oxide.

In an embodiment, the hydrogen supply layer may include an amorphous silicon.

A method of manufacturing the display device according to an embodiment may include forming an inorganic insulating layer on a substrate, forming a hydrogen supply layer on the inorganic insulating layer, forming a pixel electrode contacting the hydrogen supply layer on the hydrogen supply layer, and forming an interlayer that receives a hydrogen ion from the hydrogen supply layer on the pixel electrode.

In an embodiment, the method may further include forming a preliminary organic insulating layer on the inorganic insulating layer, forming an organic insulating layer including a first opening by etching a portion of the preliminary organic insulating layer, forming a preliminary hydrogen supply layer covering the organic insulating layer in the first opening on the organic insulating layer, and forming the hydrogen supply layer including a second opening corresponding to the first opening by etching a portion of the preliminary hydrogen supply layer.

In an embodiment, the method may further include forming a preliminary hydrogen supply layer on the inorganic insulating layer, forming a preliminary organic insulating layer on the preliminary hydrogen supply layer, forming an organic insulating layer including a first opening by etching a portion of the preliminary organic insulating layer, and forming the hydrogen supply layer including a second opening corresponding to the first opening by etching a portion of the preliminary hydrogen supply layer.

In an embodiment, the method may further include performing a hydrogen plasma treatment on at least a portion of the hydrogen supply layer, before the forming of the pixel electrode.

In a display device according to embodiments of the disclosure, a light-emitting layer included in the display device may include a quantum dot, accordingly a defect may be generated in a metal material included in an interlayer. In order to reduce the defect generated in the metal material, a positive aging process may be performed in which a material including an acid is applied to the interlayer. Meanwhile, during the positive aging process, other side effects may be generated in the interlayer.

Accordingly, in order to reduce the defect generated in the interlayer, the display device according to the disclosure may include a hydrogen supply layer. Accordingly, a hydrogen ion generated in the hydrogen supply layer may be supplied to the interlayer through a diffusion. Therefore, the hydrogen ion may be supplied to the metal material to reduce the defect without the side effects of the positive aging process.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the disclosure.

FIG. 2 is a schematic diagram of an equivalent circuit of a first sub-pixel included in the display device in FIG. 1.

FIG. 3 is a schematic cross-sectional view illustrating an embodiment of the display device in FIG. 1 taken along line I-I′.

FIGS. 4, 5, 6, 7, 8, 9, 10, 11, 12, 13, and 14 are schematic cross-sectional views illustrating a method of manufacturing the display device in FIG. 1.

FIG. 15 is a schematic cross-sectional view illustrating an embodiment of the display device in FIG. 1 taken along line I-I′.

FIGS. 16, 17, 18, 19, 20, 21, and 22 are schematic cross-sectional views illustrating a method of manufacturing the display device in FIG. 15.

FIG. 23 is a schematic cross-sectional view illustrating an embodiment of the display device in FIG. 1 taken along line I-I′.

FIG. 24 is a schematic cross-sectional view illustrating an embodiment of the display device in FIG. 1 taken along line I-I′.

### DETAILED DESCRIPTION OF THE EMBODIMENTS

Hereinafter, display devices and the methods in accordance with embodiments will be described in more detail with reference to the accompanying drawings. The same reference numerals are used for the same components in the drawings, and redundant descriptions of the same components will be omitted.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

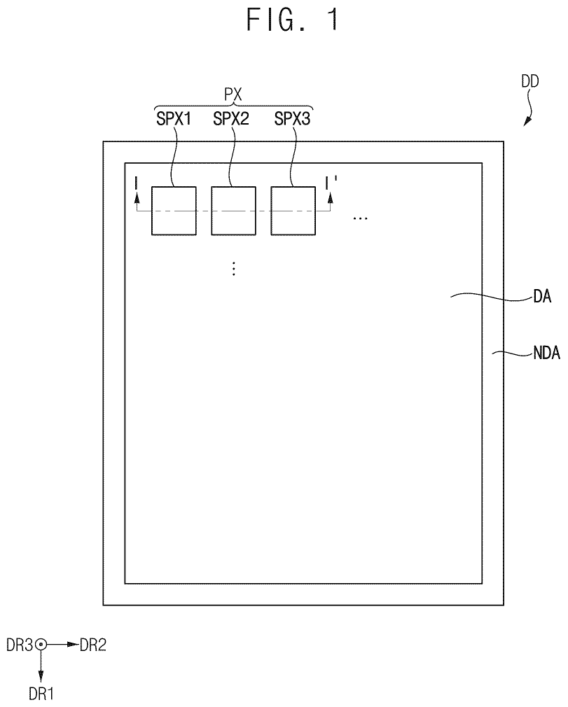

FIG. 1 is a plan view illustrating a display device according to an embodiment of the disclosure.

Referring to FIG. 1, a display device DD according to an embodiment of the disclosure may include a display area DA and a non-display area NDA. The display area DA may be an area that generates images, and the non-display area NDA may be an area that does not generate images.

At least one of a pixel PX may be disposed in the display area DA. The pixel PX may include a first sub-pixel SPX1, a second sub-pixel SPX2, and a third sub-pixel SPX3. For example, the first sub-pixel SPX1 may emit a first light, the second sub-pixel SPX2 may emit a second light, and the third sub-pixel SPX3 may emit a third light. In an embodiment, the first light may be a red light, the second light may be a green light, and the third light may be a blue light. However, the disclosure is not limited thereto. For example, the first to third sub-pixels SPX1, SPX2, and SPX3 may emit yellow, cyan, and magenta lights, respectively.

The first to third sub-pixels SPX1, SPX2, and SPX3 may be arranged in a first direction DR1 and a second direction DR2 intersecting the first direction DR1, repeatedly, in a plan view. For example, the second sub-pixel SPX2 may be adjacent to the first sub-pixel SPX1 in the second direction DR2. The third sub-pixel SPX3 may be adjacent to the second sub-pixel SPX2 in the second direction DR2.

The non-display area NDA may be adjacent to the display area DA. For example, the non-display area NDA may surround at least one side of the display area DA. A driver may be disposed in the non-display area NDA. The driver may supply a signal or a voltage to the pixel PX. For example, the driver may include a data driver, gate driver, and the like.

In this specification, a plane may be defined by the first direction DR1 and the second direction DR2. For example, the second direction DR2 may be perpendicular to the first direction DR1. The third direction DR3 may be perpendicular to the plane.

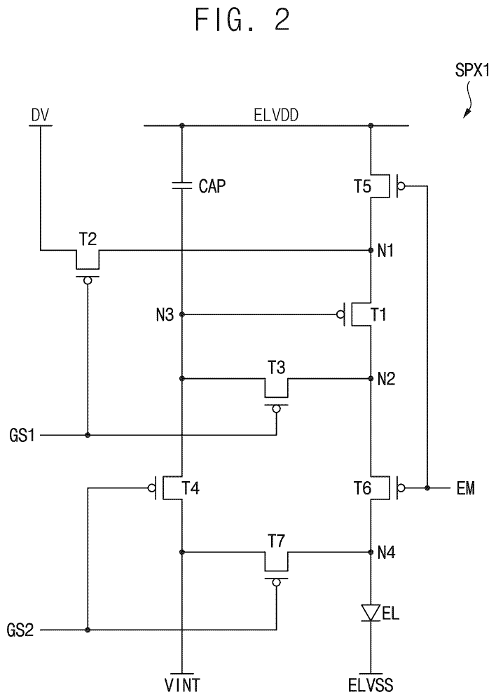

FIG. 2 is a schematic diagram of an equivalent circuit of a first sub-pixel included in the display device in FIG. 1.

Referring to FIG. 2, the first sub-pixel SPX1 may include a first transistor T1, a second transistor T2, a third transistor T3, a fourth transistor T4, a fifth transistor T5, a sixth transistor T6, a seventh transistor T7, a capacitor CAP, and a light-emitting element EL.

The first transistor T1 may be connected between a first node N1 and a second node N2. The first transistor T1 may include a source electrode connected to the first node N1, a drain electrode connected to the second node N2, and a gate electrode connected to a third node N3.

The second transistor T2 may be connected between the first node N1 and a data line. The second transistor T2 may include a source electrode configured to receive a data voltage DV, a drain electrode connected to the first node N1, and a gate electrode configured to receive a first gate signal GS1.

The third transistor T3 may be connected between the second node N2 and the third node N3. The third transistor T3 may include a source electrode connected to the third node N3, a drain electrode connected to the second node N2, and a gate electrode configured to receive the first gate signal GS1.

The fourth transistor T4 may be connected between an initialization voltage line and the third node N3. The fourth transistor T4 may include a source electrode configured to receive an initialization voltage VINT, a drain electrode connected to the third node N3, and a gate electrode configured to receive a second gate signal GS2.

The fifth transistor T5 may be connected between a first power configured to supply a high power voltage ELVDD and the first node N1. The fifth transistor T5 may include a source electrode configured to receive the high power voltage ELVDD, a drain electrode connected to the first node N1, and a gate electrode configured to receive a light control signal EM.

The sixth transistor T6 may be connected between the second node N2 and a fourth node N4. The sixth transistor T6 may include a source electrode connected to the second node N2, a drain electrode connected to the fourth node N4, and a gate electrode configured to receive the light control signal EM.

The seventh transistor T7 may be connected between the initialization voltage line and the fourth node N4. The seventh transistor T7 may include a source electrode configured to receive the initialization voltage VINT, a drain electrode connected to the fourth node N4, and a gate electrode configured to receive the gate signal GS2.

The capacitor CAP may be connected between the first power and the third node N3. The capacitor CAP may include a first capacitor electrode connected to the third node and a second capacitor electrode configured to receive the high power voltage ELVDD.

The light-emitting element EL may be connected between the fourth node N4 and a second power configured to supply a low power voltage ELVSS. A voltage level of the low power voltage ELVSS may be lower than a voltage level of the high power voltage ELVDD. The light-emitting element EL may include a first electrode connected to the fourth node N4 and a second electrode configured to receive the low power voltage ELVSS.

In an embodiment, each of the first to seventh transistors T1, T2, T3, T4, T5, T6, and T7 may be a PMOS transistor. However, the disclosure is not limited thereto, and in another embodiment, at least one of the first to seventh transistors T1, T2, T3, T4, T5, T6, and T7 may be a NMOS transistor.

FIG. 2 illustrates that the first sub-pixel SPX1 includes seven transistors and one capacitor, however, the disclosure is not limited thereto. For example, the first sub-pixel SPX1 may include two to six or eight or more transistors and two or more capacitors.

Each of the second and the third transistors SPX2, SPX3 may have a circuit structure substantially equal to the first transistor SPX1.

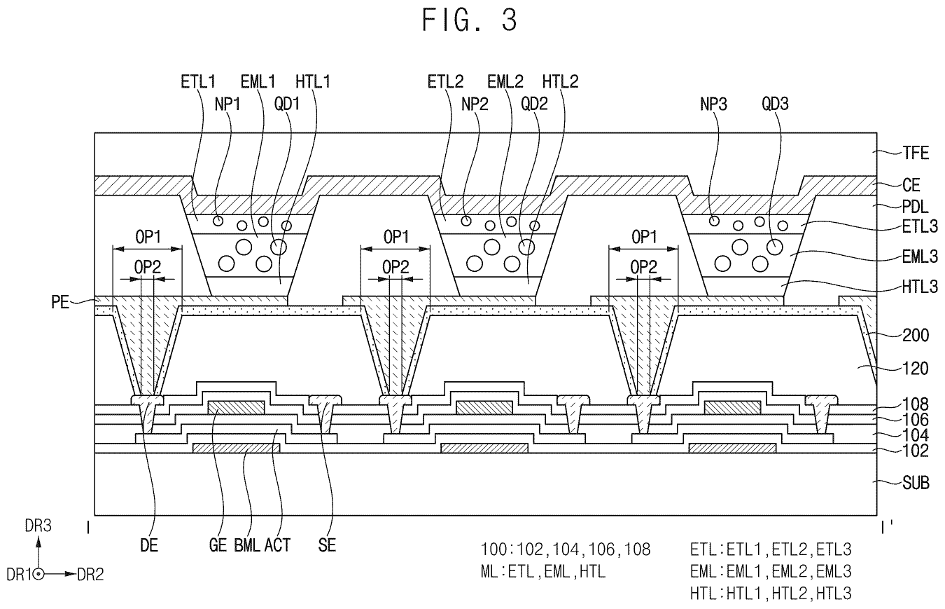

FIG. 3 is a schematic cross-sectional view illustrating an embodiment of the display device in FIG. 1 taken along line I-I′.

Referring to FIG. 3, the display device DD according to an embodiment of the disclosure may include a substrate SUB, a bottom light blocking layer BML, a buffer layer 102, an active layer ACT, a first gate insulating layer 104, a gate electrode GE, a second gate insulating layer 106, a third gate insulating layer 108, a source electrode SE, a drain electrode DE, an organic insulating layer 120, a hydrogen supply layer 200, a pixel electrode PE, a pixel defining layer PDL, first to third hole auxiliary layers HTL1, HTL2, and HTL3, first to third light-emitting layers EML1, EML2, and EML3, first to third electron auxiliary layer ETL1, ETL2, and ETL3, a common electrode CE, and an encapsulation layer TFE. The first to third light-emitting layers EML1, EML2, and EML3 may include first to third quantum dots QD1, QD2, and QD3 respectively, and the first to third electron auxiliary layer ETL1, ETL2, and ETL3 may include first to third nano particles NP1, NP2, and NP3 respectively. The first to third light-emitting layers EML1, EML2, and EML3 may correspond to the first to third sub-pixels SPX1, SPX2, and SPX3 in FIG. 1.

The substrate SUB may include a transparent or an opaque material. The substrate SUB may be a transparent resin substrate. Examples of the transparent resin substrate may include a polyimide substrate. For example, the polyimide substrate SUB may include a first organic layer, a first barrier layer, a second organic layer, and the like. In another embodiment, the substrate SUB may be a quartz substrate, a synthetic quartz substrate, a calcium fluoride substrate, a non-alkali glass substrate, or the like. These may be used alone or in combination with each other.

The bottom light blocking layer BML may be disposed on the substrate SUB. The bottom light blocking layer BML may block an external light or a light from the light-emitting element (e.g., the light-emitting element EL in FIG. 2) from flowing into the active layer ACT. The bottom light blocking layer BML may include a metal material. For example, the bottom light blocking layer BML may include a silver (Ag), a nickel (Ni), a gold (Au), a platinum (Pt), an aluminum (Al), a copper (Cu), a molybdenum (Mo), a titanium (Ti), a neodymium (Nd), or the like. These may be used alone or in combination with each other.

The buffer layer 102 may be disposed on the bottom light blocking layer BML. The buffer layer 102 may prevent impurities from diffusing from the substrate SUB to the active layer ACT. The buffer layer 102 may include an inorganic insulating material. For example, the buffer layer 102 may include a silicon nitride (SiNₓ), a silicon oxide (SiOₓ), a silicon oxynitride (SiOₓN_{y}), or the like. These may be used alone or in combination with each other.

The active layer ACT may be disposed on the buffer layer 102. The active layer ACT may be disposed to correspond to each of the first to third sub-pixels SPX1, SPX2, and SPX3. The active layer ACT may overlap the bottom light blocking layer BML in a plan view. As the active layer ACT overlaps the bottom light blocking layer BML, a photocurrent may be prevented from generating in the active layer ACT.

In an embodiment, the active layer ACT may include an oxide semiconductor, an amorphous silicon, or a polycrystalline silicon. For example, the oxide semiconductor may include a zinc (Zn), an indium zinc (In—Zn) oxide, a gallium indium zinc (Ga—In—Zn) oxide, and the like. These may be used alone or in combination with each other.

The active layer ACT may include source and drain regions doped by impurities, and a channel region disposed between the source and drain regions.

The first gate insulating layer 104 may be disposed on the buffer layer 102. The first gate insulating layer 104 may cover the active layer ACT on the buffer layer 102. For example, the first gate insulating layer 104 may have a substantially uniform thickness along a profile of the active layer ACT. In another embodiment, the first gate insulating layer 104 may sufficiently cover the active layer ACT and may have a substantially flat upper surface without creating a step on the active layer ACT.

The first gate insulating layer 104 may include an inorganic insulating material. For example, the first gate insulating layer 104 may include a silicon nitride (SiNₓ), a silicon oxide (SiOₓ), a silicon oxynitride (SiOₓN_{y}), or the like. These may be used alone or in combination with each other.

The gate electrode GE may be disposed on the first gate insulating layer 104. The gate electrode GE may overlap the channel area of the active layer ACT in a plan view. The gate electrode GE may include an aluminum (Al), a platinum (Pt), a palladium (Pd), a silver (Ag), a magnesium (Mg), a gold (Au), a nickel (Ni), a neodymium (Nd), an iridium (Ir), a chromium (Cr), a lithium (Li), a calcium (Ca), a molybdenum (Mo), a titanium (Ti), a tungsten (W), a copper (Cu), or the like. These may be used alone or in combination with each other.

The second gate insulating layer 106 may be disposed on the first gate insulating layer 104. The second gate insulating layer 106 may cover the gate electrode GE. For example, the second gate insulating layer 106 may have a substantially uniform thickness along a profile of the gate electrode GE. In another embodiment, the second gate insulating layer 106 may sufficiently cover the gate electrode GE and may have a substantially flat upper surface without creating a step on the gate electrode GE.

The second gate insulating layer 106 may include an inorganic insulating material. For example, the second gate insulating layer 106 may include a silicon nitride (SiNₓ), a silicon oxide (SiOₓ), a silicon oxynitride (SiOₓN_{y}), or the like. These may be used alone or in combination with each other.

The third gate insulating layer 108 may be disposed on the second gate insulating layer 106. The third gate insulating layer 108 may include an inorganic insulating material. For example, the third gate insulating layer 108 may include a silicon nitride (SiNₓ), a silicon oxide (SiOₓ), a silicon oxynitride (SiOₓN_{y}), or the like. These may be used alone or in combination with each other.

The source electrode SE and the gate electrode GE may be disposed on the third gate insulating layer 108. Each of the source electrode SE and the gate electrode GE may be connected to the active layer ACT by penetrating the first and the second gate insulating layers 104 and 106. The source electrode SE and the gate electrode GE may be connected to the source region and the drain region, respectively. Although not shown in FIG. 3, the source electrode SE and of the gate electrode GE may be connected to the bottom light blocking layer BML by penetrating the first and the second gate insulating layers 104 and 106.

The source and drain electrodes SE and DE may include a metal, and alloy, a conductive metal oxide, a conductive metal nitride, a transparent conductive material, or the like. These may be used alone or in combination with each other.

Accordingly, the active layer ACT, the gate electrode GE, the source electrode SE, and the drain electrode DE may form a transistor. The transistor may correspond to any of the first to seventh transistors T1, T2, T3, T4, T5, T6, and T7 in FIG. 2.

In this specification, an inorganic insulating layer 100 including the buffer layer 102, the first gate insulating layer 104, the second gate insulating layer 106, the third gate insulating layer 108 may be defined.

The organic insulating layer 120 may be disposed on the inorganic insulating layer 100. The organic insulating layer 120 may include an organic insulating material such as a polyimide (PI).

A first opening OP1 may be defining in the organic insulating layer 120. The first opening OP1 may penetrate the organic insulating layer 120. For example, a portion of the drain electrode DE may be exposed through the first opening OP1 of the organic insulating layer 120. In another embodiment, a portion of the source electrode SE may be exposed through the first opening OP1.

The hydrogen supply layer 200 may be disposed on the organic insulating layer 120. The hydrogen supply layer 200 may supply a hydrogen ion to an interlayer ML disposed on an upper portion of the hydrogen supply layer 200. For example, the hydrogen ion may diffuse from the hydrogen supply layer 200 to the interlayer ML.

In an embodiment, the hydrogen supply layer 200 may cover upper and side surfaces of the organic insulating layer 120. For example, the hydrogen supply layer 200 may cover profile of each of the upper and side surfaces of the organic insulating layer 120 in which the first opening OP1 is defined, with a substantially uniform thickness.

A second opening OP2 may be defined in the hydrogen supply layer 200. The second opening OP2 may overlap the first opening OP1, in a plan view. For example, the second opening OP2 may form a hole by being connected to the first opening OP1 in the third direction DR3. A portion of the transistor may be exposed by the first and the second opening OP1 and OP2.

In an embodiment, the hydrogen supply layer 200 may include a silicon nitride (SiNₓ). A hydrogen ion generated from the silicon nitride (SiNₓ) may diffuse into the interlayer ML disposed on an upper portion of the hydrogen supply layer 200. In order to increase an amount of hydrogen ion generated in the hydrogen supply layer 200, the hydrogen supply layer 200 including the silicon nitride (SiNₓ) may be treated with a hydrogen plasma treatment.

In another embodiment, the hydrogen supply layer 200 may include an amorphous silicon. A hydrogen ion may be generated from a dangling bond in the amorphous silicon. Accordingly, the hydrogen ion generated from the amorphous silicon may diffuse into the interlayer ML. In order to increase the amount of hydrogen ion generated in the hydrogen supply layer 200, the hydrogen supply layer 200 including the amorphous silicon may be treated with a hydrogen plasma treatment.

In still another embodiment, the hydrogen supply layer 200 may include a silicon oxide (SiOₓ). A hydrogen ion generated from the silicon oxide (SiOₓ) may diffuse into the interlayer ML disposed on an upper portion of the hydrogen supply layer 200. In order to increase the amount of hydrogen ion generated in the hydrogen supply layer 200, the hydrogen supply layer 200 including the silicon oxide (SiOₓ) may be treated with a hydrogen plasma treatment.

The pixel electrode PE may be disposed on the hydrogen supply layer 200. For example, the pixel electrode PE may contact the hydrogen supply layer 200. In an embodiment, an upper portion of the hydrogen supply layer 200 that faces in the third direction DR3 may contact the pixel electrode PE.

The pixel electrode PE may be disposed to correspond to the first to third sub-pixels SPX1, SPX2, and SPX3 in FIG. 1.

For example, the pixel electrode PE may contact the drain electrode DE through the first opening OP1 and the second opening OP2. In another embodiment, the pixel electrode PE may contact the source electrode SE through the first opening OP1 and the second opening OP2.

At least a portion of the pixel electrode PE may contact (e.g., directly contact) the hydrogen supply layer 200. At least a portion of an upper surface of the pixel electrode PE may contact (e.g., directly contact) the hole auxiliary layer HTL. As described above, a surface of the pixel electrode PE opposite to the upper surface may contact the hydrogen supply layer 200.

In an embodiment, the pixel electrode PE may operate as an anode. The pixel electrode PE may include a metal, an alloy, a metal nitride, a conductive metal oxide, a transparent conductive material, or the like. These may be used alone or in combination with each other.

Each of the first to third hole auxiliary layers HTL1, HTL2, and HTL3 may be disposed on the pixel electrode PE. For example, each of the first to third hole auxiliary layers HTL1, HTL2, and HTL3 may include a hole injection layer and/or a hole transport layer. However, the disclosure is not limited thereto. For example, each of the first to third hole auxiliary layers HTL1, HTL2, and HTL3 may further include a buffer layer or an electron blocking layer. The buffer layer may serve to increase light emission efficiency by compensating for an optical resonance distance depending on the wavelength of light emitted from the first to third light-emitting layers EML1, EML2, and EML3. The electron blocking layer may serve to prevent electron injection from the first to third electron auxiliary layers ETL1, ETL2, and ETL3. In this specification, the hole auxiliary layer HTL may be at least one of the first to third hole auxiliary layers HTL1, HTL2, and HTL3.

Each of the first to third light-emitting layers EML1, EML2, and EML3 may be disposed on the first to third hole auxiliary layers HTL1, HTL2, and HTL3. The first to third light-emitting layers EML1, EML2, and EML3 may include first to third quantum dots QD1, QD2, and QD3, respectively. By adjusting the composition and/or size of the first to third quantum dots QD1, QD2, and QD3, the emission wavelengths of the first to third quantum dots QD1, QD2, and QD3 may be adjusted. In this specification, the light-emitting layer EML may be at least one of the first to third light-emitting layers EML1, EML2, and EML3.

In one embodiment, each of the first to third quantum dots QD1, QD2, QD3 may include a group II-VI compound, a group III-V compound, a group IV-VI compound, a group IV element or compound, and the like. These may be used alone or in combination with each other. For example, the II-VI group compounds may include CdSe, CdTe, ZnS, ZnSe, ZnTe, ZnO, HgS, HgSe, and the like. The group III-V compounds may include GaN, GaP, GaAs, GaSb, AlN, AlP, and the like. The IV-VI group compounds may include SnS, SnSe, SnTe, PbS, PbSe, and the like. The group IV elements may include Si, Ge, and the like. The group IV compounds may include SiC, SiGe, and the like.

Each of the first to third electron auxiliary layers ETL1, ETL2, and ETL3 may be disposed on the first to third light-emitting layers EML1, EML2, and EML3. Each of the first to third electron auxiliary layers ETL1, ETL2, and ETL3 may include an electron transport layer and/or an electron injection layer. However, the disclosure is not limited thereto. For example, each of the first to third electron auxiliary layers ETL1, ETL2, and ETL3 may further include a hole blocking layer. The hole blocking layer may serve to prevent hole injection from the first to third hole auxiliary layers HTL1, HTL2, and HTL3. In this specification, the electron auxiliary layer ETL may be at least one of the first to third electron auxiliary layers ETL1, ETL2, and ETL3.

In an embodiment, the first to third electron auxiliary layers ETL1, ETL2, and ETL3 may include first to third nanoparticles NP1, NP2, and NP3, respectively. In an embodiment, each of the first to third nanoparticles NP1, NP2, and NP3 may include a metal oxide. For example, each of the first to third nanoparticles NP1, NP2, and NP3 may include zinc oxide (ZnO), zinc magnesium oxide (ZnMgO), or the like. These may be used alone or in combination with each other.

The pixel defining layer PDL may be disposed on the pixel electrode PE. For example, an opening in which the first to third light-emitting layers EML1, EML2, and EML3 are disposed may be formed in the pixel defining layer PDL. The pixel defining layer PDL may include an organic material and/or an inorganic material. For example, the pixel defining layer PDL may include a photoresist, a polyacrylic resin, a polyimide resin, a polyamide resin, a siloxane resin, an acrylic resin, an epoxy resin, or the like. These may be used alone or in combination with each other.

The interlayer ML may include the electron auxiliary layer ETL, the light-emitting layer EML, and the hole auxiliary layer HTL. The interlayer ML may receive a hydrogen ion from the hydrogen supply layer 200.

The common electrode CE may be disposed on the first to third electron auxiliary layers ETL1, ETL2, and ETL3 and the pixel defining layer PDL. The common electrode CE may be continuously disposed across the first to third sub-pixels SPX1, SPX2, and SPX3. However, the disclosure is not limited thereto, and in another embodiment, the common electrode CE may cover a portion of each of the first to third electron auxiliary layers ETL1, ETL2, and ETL3.

The common electrode CE may include a metal, an alloy, a metal nitride, a conductive metal oxide, a transparent conductive material, or the like. These may be used alone or in combination with each other. For example, the common electrode CE may operate as a cathode.

The encapsulation layer TFE may be disposed on the common electrode CE. The encapsulation layer TFE may include at least one inorganic encapsulation layer and at least one organic encapsulation layer. For example, the inorganic encapsulation layer may include silicon oxide, silicon nitride, silicon oxynitride, etc., and the organic encapsulation layer may include a cured polymer such as polyacrylate.

As the display device (e.g., the display device DD in FIG. 1) includes a quantum dot in the light-emitting layer EML, a defect may generate in a metal material included in the interlayer ML (e.g., the electron auxiliary layer ETL included in the interlayer ML). In order to reduce the defect generated in the metal material, a positive aging process may be performed in which a material containing acid is applied to the interlayer ML. During the positive aging process, other side effects may be generated in the interlayer ML.

Accordingly, in order to reduce the defect generated in the interlayer ML, the display device according to an embodiment of the disclosure may include the hydrogen supply layer 200. As the display device includes the hydrogen supply layer 200, a hydrogen ion generated in the hydrogen supply layer 200 may be supplied to the interlayer ML through diffusion. The hydrogen ion may be supplied to the metal material to reduce the defect without the side effects of positive aging.

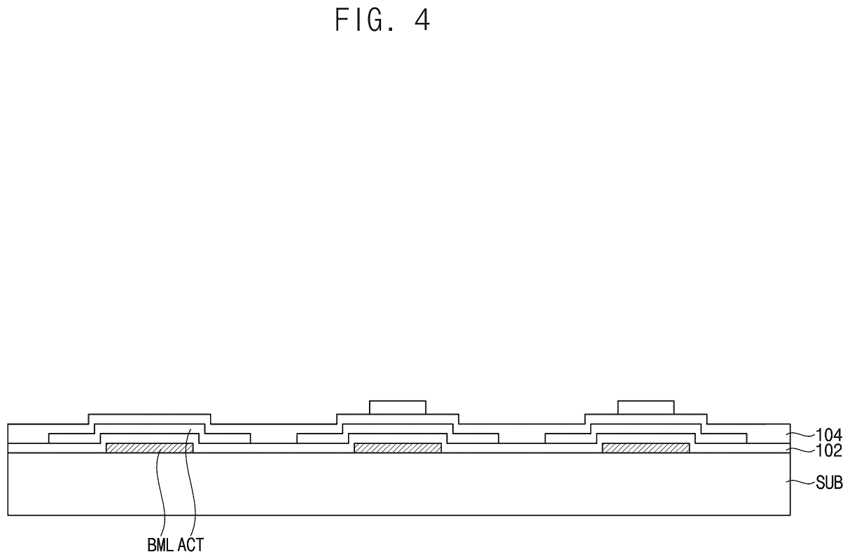

FIGS. 4, 5, 6, 7, 8, 9, 10, 11, 12, 13, and 14 are schematic cross-sectional views illustrating a method of manufacturing the display device in FIG. 1. Hereinafter, descriptions that overlap those described with reference to FIG. 3 will be omitted or simplified.

Referring to FIG. 4, the bottom light blocking layer BML, the buffer layer 102, the first gate insulating layer 104, and the active layer ACT may be formed in the stated order on the substrate SUB.

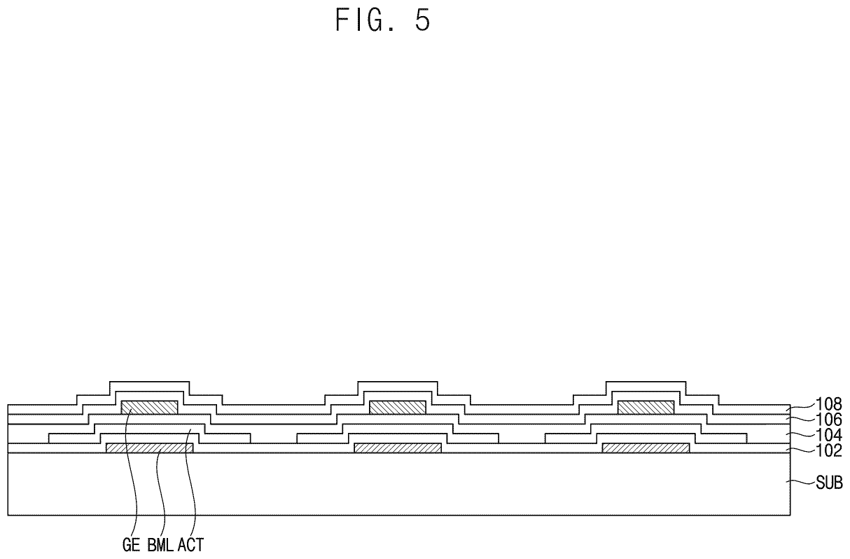

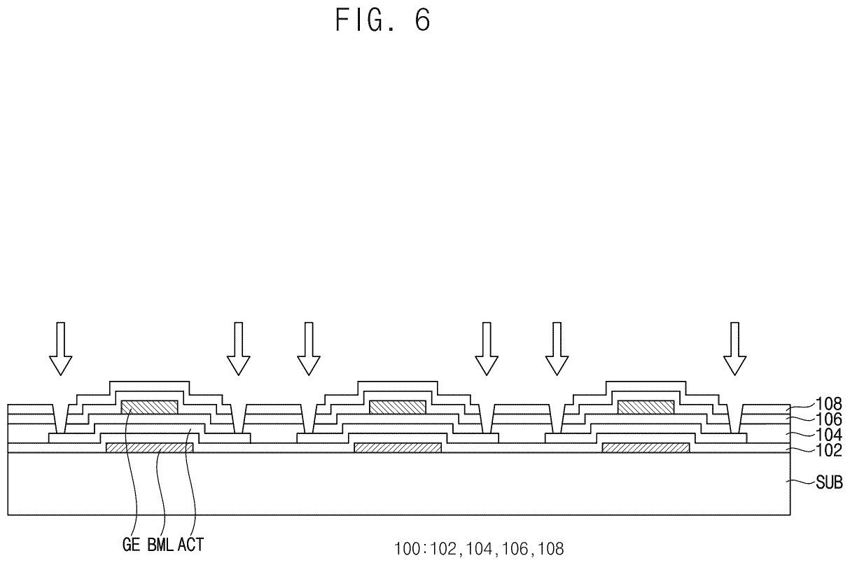

Referring to FIGS. 5 and 6, the second gate insulating layer 106, the gate electrode GE, and the third gate insulating layer 108 may be formed on the first gate insulating layer 104, in the stated order. A portion of each of the first to third gate insulating layers 104, 106, and 108 overlapping ends of the active layer ACT may be removed through an etching process. For example, a through hole penetrating a portion of each of the first to third gate insulating layers may be formed through the etching process. For example, the through hole may overlap the source region and the drain region of the active layer ACT in a plan view.

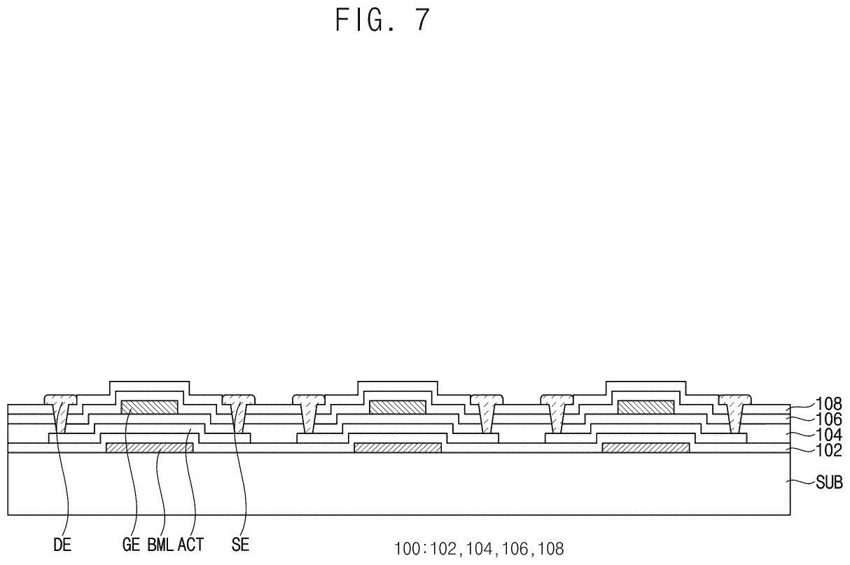

Referring to FIG. 7, the source electrode SE and the drain electrode DE may be formed on the third gate insulating layer 108. The through hole may be filled with the source electrode SE and the drain electrode DE. For example, the source electrode SE may contact the source region and the drain electrode DE may contact the drain region through the through hole.

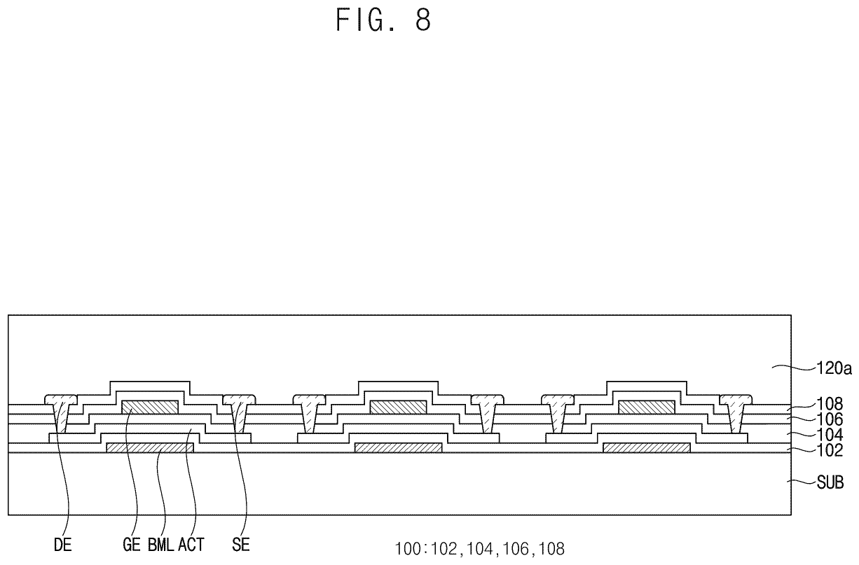

Referring to FIG. 8, a preliminary organic insulating layer 120a may be formed on the inorganic insulating layer 100. For example, the preliminary organic insulating layer 120a may cover the third gate insulating layer 108. An upper portion of the preliminary organic insulating layer 120a may have a substantially flat surface. The preliminary organic insulating layer 120a and the organic insulating layer 120 may include a same material. For example, the preliminary organic insulating layer 120a may be formed using an organic insulating material such as polyimide (PI).

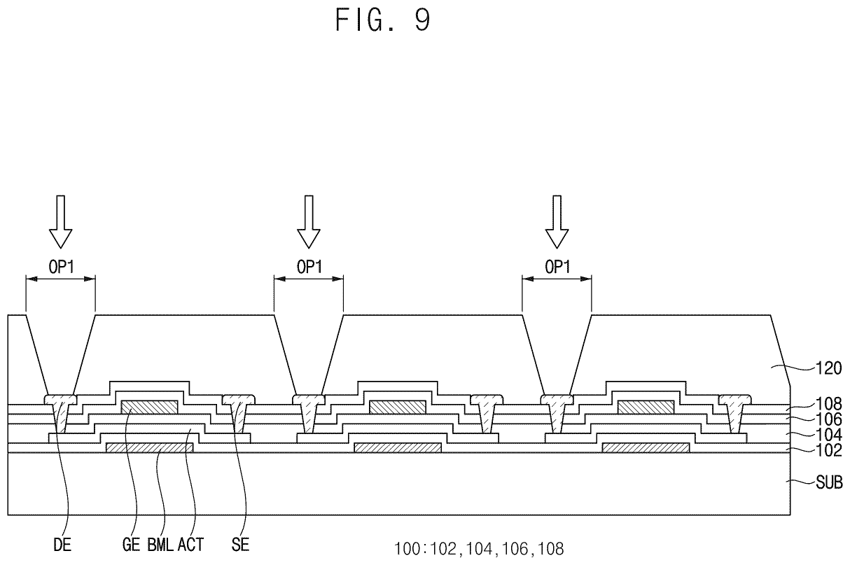

Referring to FIG. 9, a portion of the preliminary organic insulating layer 120a may be removed through an etching process. For example, a portion of the preliminary organic insulating layer 120a may be etched to form the organic insulating layer 120 in which the first opening OP1 is defined. For example, a first opening OP1 penetrating a portion of the organic insulating layer 120 in a thickness direction (e.g., the third direction DR3) may be defined in the organic insulating layer 120. The first opening OP1 may become wider toward an upper portion of the organic insulating layer 120. However, the disclosure is not limited thereto, and the organic insulating layer 120 in which the first opening OP1 is defined may have various shapes.

The first opening OP1 may be a through hole to connect the transistor and the interlayer ML electrically. Accordingly, a portion of the drain electrode DE may be exposed through the first opening OP1. In another embodiment, a portion of the source electrode SE may be exposed through the first opening OP1.

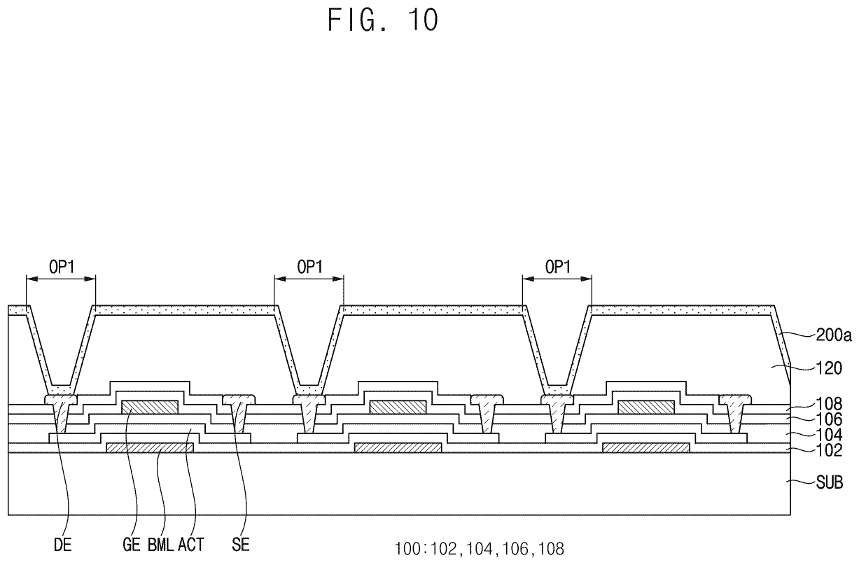

Referring to FIG. 10, a preliminary hydrogen supply layer 200a may be formed on the organic insulating layer 120. For example, the preliminary hydrogen supply layer 200a may cover the first opening OP1. For example, the preliminary hydrogen supply layer 200a may cover the drain electrode DE exposed through the first opening OP1.

The preliminary hydrogen supply layer 200a and the hydrogen supply layer 200 may include a same material. For example, the preliminary hydrogen supply layer 200a may include an inorganic material. The preliminary hydrogen supply layer 200a may have substantially the same thickness along the profile of the organic insulating layer 120.

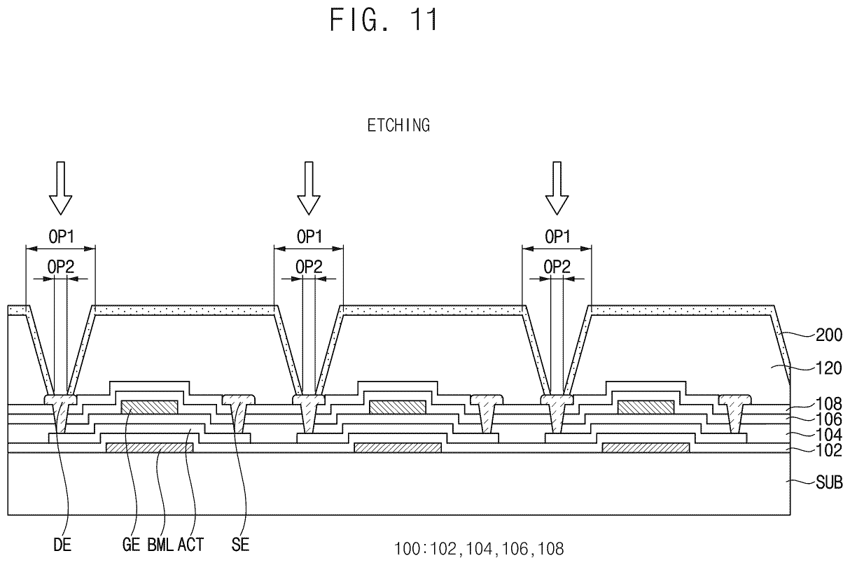

Referring to FIG. 11, a portion of the preliminary hydrogen supply layer 200a may be removed through an etching process. A portion of the preliminary hydrogen supply layer 200a may be etched to form the hydrogen supply layer 200 in which second opening OP2 is defined. For example, a second opening OP2 penetrating a portion of the hydrogen supply layer 200a in a thickness (e.g., the third direction DR3) direction may be defined.

A portion of the drain electrode DE may be exposed through the second opening OP2. In another embodiment, a portion of the source electrode SE may be exposed through the second opening OP2. The second opening OP2 may be a through hole to connect the transistor and the interlayer ML electrically with the first opening OP1.

In an embodiment, the second opening OP2 may be located to correspond to the first opening OP1. For example, the second opening OP2 may overlap the first opening OP1 in a plan view. A width of the second opening OP2 may be less than a width of the first opening OP1.

The second opening OP2 may have a constant width from a lower portion to an upper portion of the hydrogen supply layer 200. However, the disclosure is not limited thereto, and the second opening OP2 may have various shapes to electrically connect the pixel electrode PE to the source and drain electrodes SE and DE.

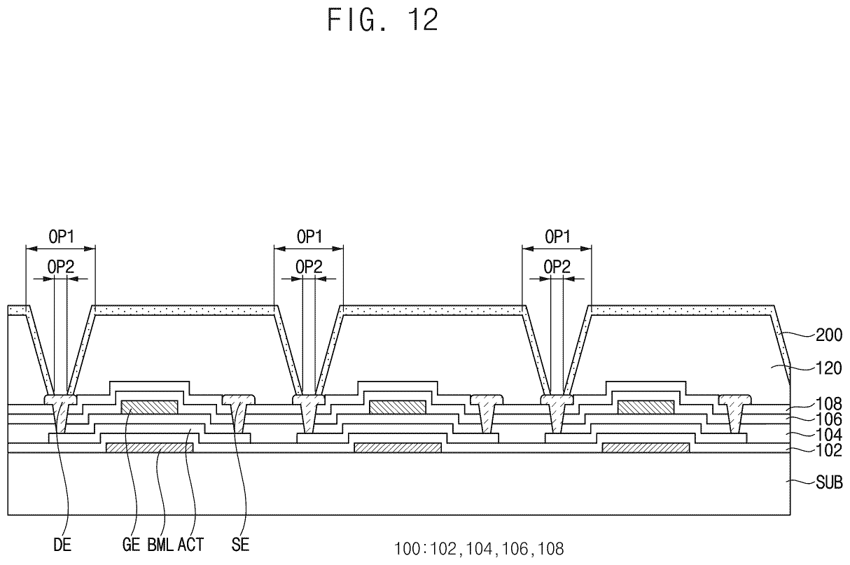

Referring to FIG. 12, at least a portion of the hydrogen supply layer 200 may be treated with a hydrogen plasma treatment. For example, an upper surface of the hydrogen supply layer 200 may be treated with the hydrogen plasma treatment. Accordingly, a concentration of a hydrogen ion on the upper surface of the hydrogen supply layer 200 may increase relatively more than before the hydrogen plasma treatment. The hydrogen ion generated in the hydrogen supply layer 200 may diffuse more readily toward the interlayer ML. However, the disclosure is not limited to hydrogen plasma treatment on an upper portion of the hydrogen supply layer 200.

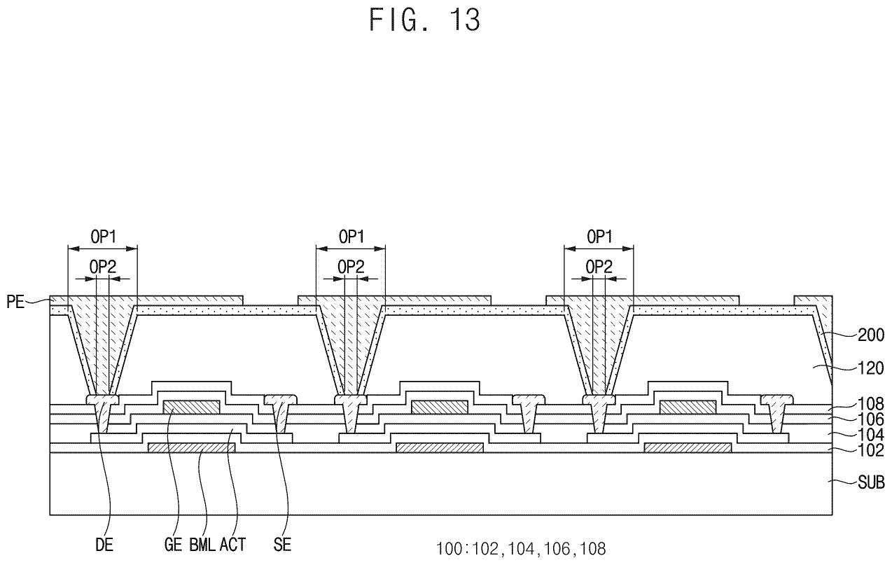

Referring to FIG. 13, the pixel electrode PE may be formed on the hydrogen supply layer 200. For example, the pixel electrode PE may fill the first and second openings OP1 and OP2. The pixel electrode PE may contact the drain electrode DE through the first and second openings OP1 and OP2. The pixel electrode PE may contact (e.g., directly contact) an upper portion of the hydrogen supply layer 200

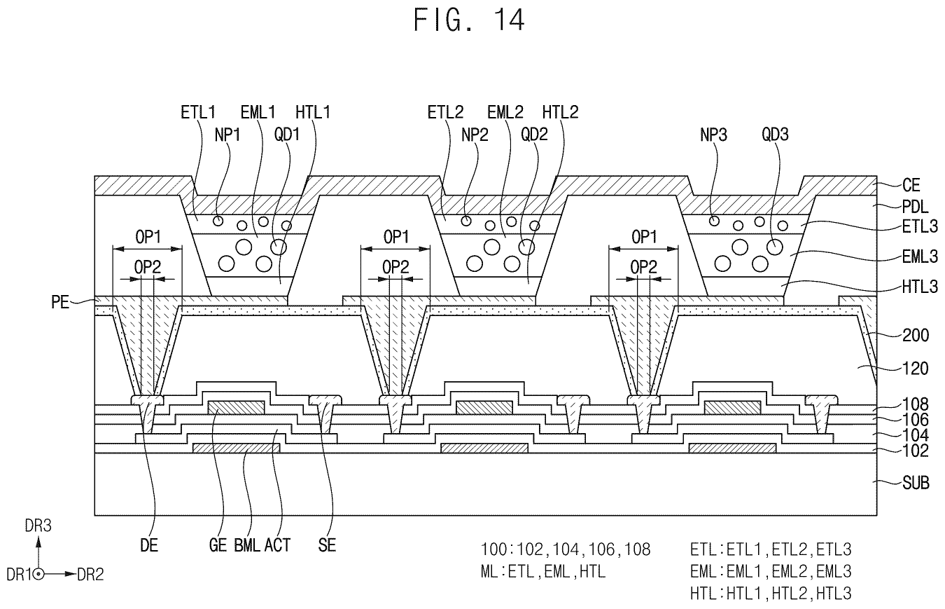

Referring to FIG. 14, the pixel defining layer PDL, the interlayer ML, and the common electrode CE may be formed on the pixel electrode PE. The encapsulation layer TFE may be formed on the common electrode CE. Accordingly, the display device DD in FIG. 1 that includes a structure shown in FIG. 3 may be manufactured.

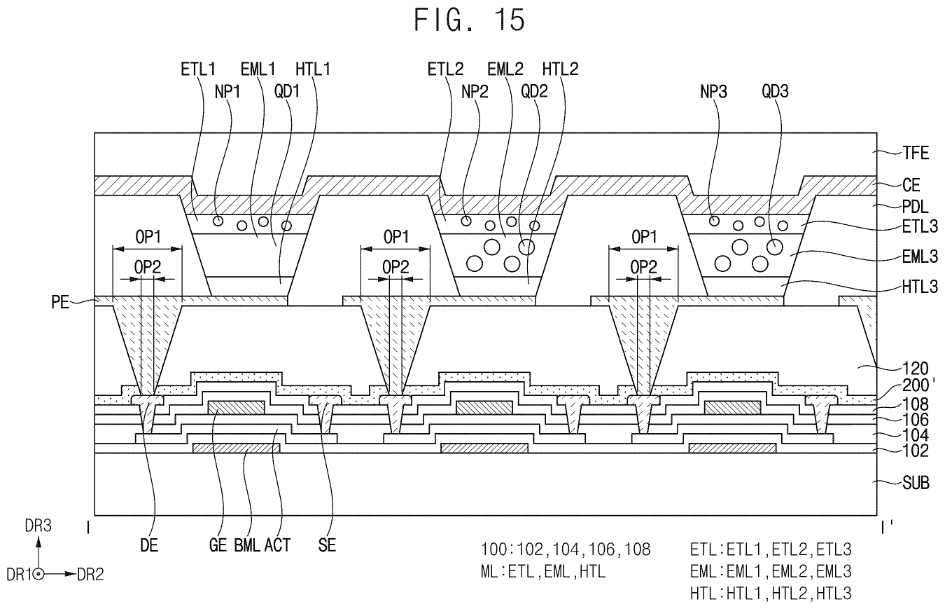

FIG. 15 is a schematic cross-sectional view illustrating an embodiment of the display device in FIG. 1 taken along line I-I′.

Hereinafter, descriptions that overlap those described with reference to FIG. 3 will be omitted or simplified.

Referring to FIG. 15, a hydrogen supply layer 200′ may be disposed between the inorganic insulating layer 100 and the organic insulating layer 120. For example, the hydrogen supply layer 200′ may contact each of the inorganic insulating layer 100 and the organic insulating layer 120. For example, a lower portion of the hydrogen supply layer 200′ may contact the third gate insulating layer 108. An upper portion of the hydrogen supply layer 200′ may contact the organic insulating layer 120.

A second opening OP2 may be defined in the hydrogen supply layer 200′. The second opening OP2 may overlap the first opening OP1 in a plan view. A width of the first opening OP1 may be greater than a width of the second opening OP2.

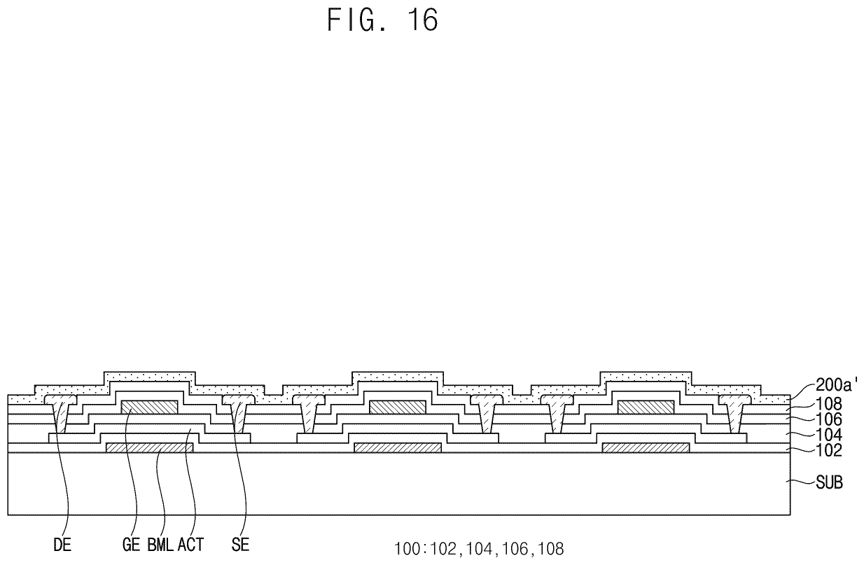

FIGS. 16, 17, 18, 19, 20, 21, and 22 are schematic cross-sectional views illustrating a method of manufacturing the display device in FIG. 15.

Referring to FIG. 16, a preliminary hydrogen supply layer 200a′ may be formed on the inorganic insulating layer 100. For example, the preliminary hydrogen supply layer 200a′ may cover each of the third gate insulating layer 108, the source electrode SE, and the drain electrode DE. For example, the preliminary hydrogen supply layer 200a′ may have a substantially uniform thickness along a profile of each of the third gate insulating layer 108, the source electrode SE, and the drain electrode DE.

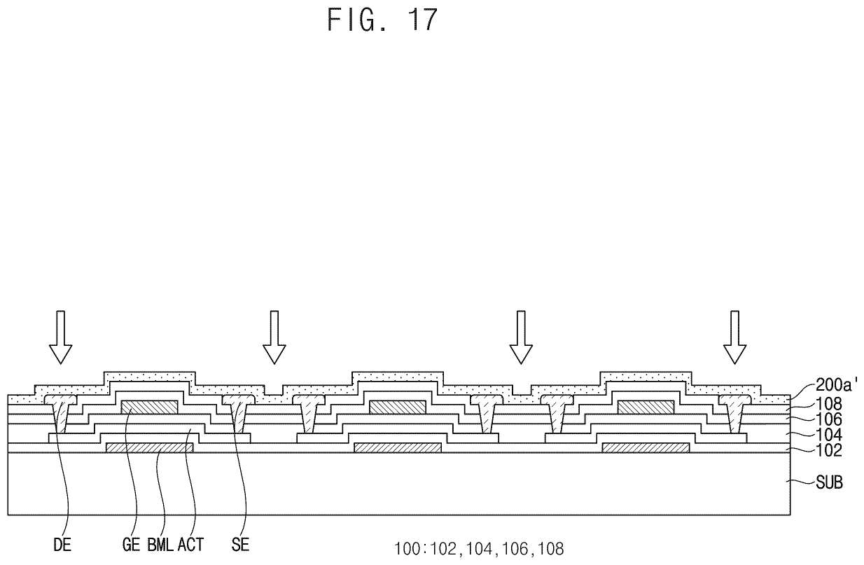

Referring to FIG. 17, at least a portion of the preliminary hydrogen supply layer 200a′ may be treated with a hydrogen plasma treatment. For example, an upper surface of the preliminary hydrogen supply layer 200a′ may be treated with a hydrogen plasma treatment. Accordingly, a concentration of a hydrogen ion on the upper surface of the hydrogen supply layer 200a′ may increase relatively more than before the hydrogen plasma treatment.

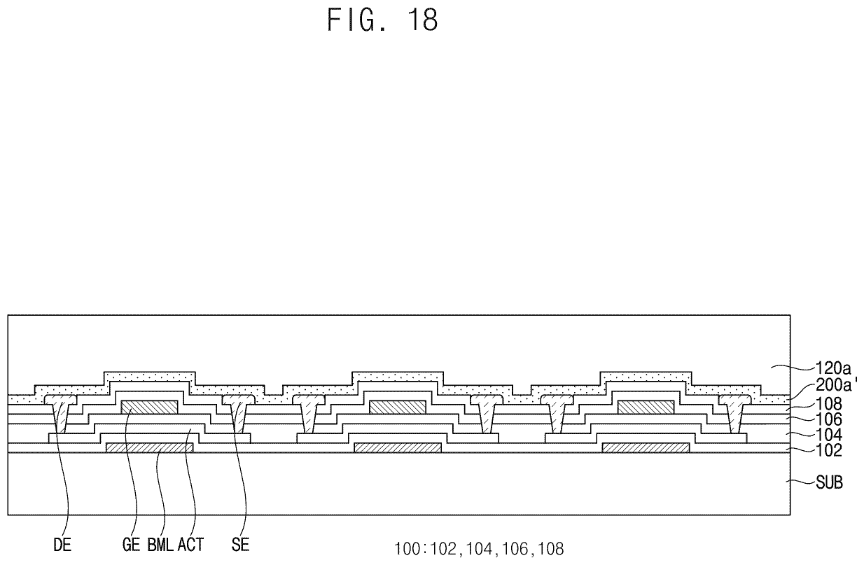

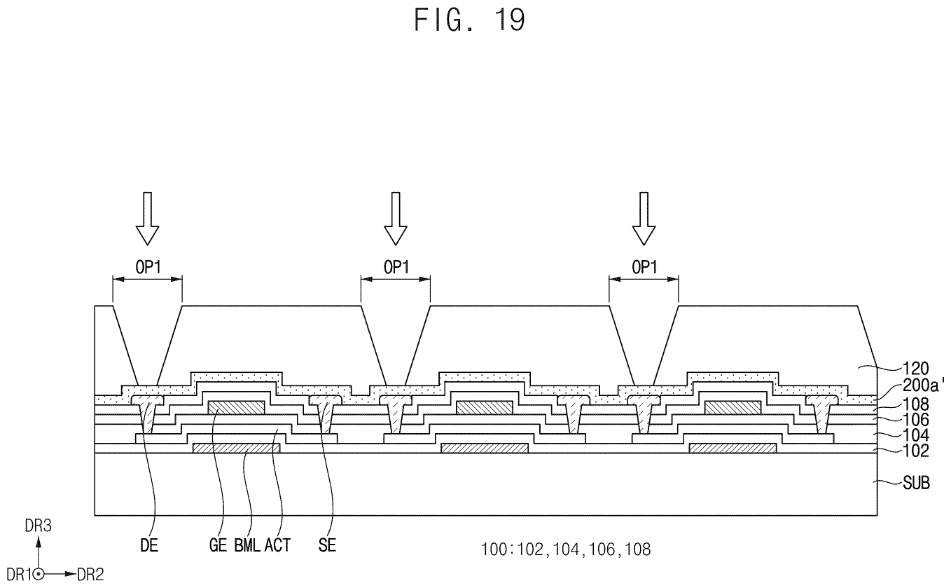

Referring to FIGS. 18 and 19, a preliminary organic insulating layer 120a may be formed on the hydrogen supply layer 200a′. A portion of the preliminary organic insulating layer 120a may be removed through an etching process. Accordingly, the organic insulating layer 120 in which the first opening OP1 is defined may be formed. A portion of the hydrogen supply layer 200a′ may be exposed through the first opening OP1. A portion of the organic insulating layer 120 that is not removed through the etching process may overlap the gate electrode GE in a plan view.

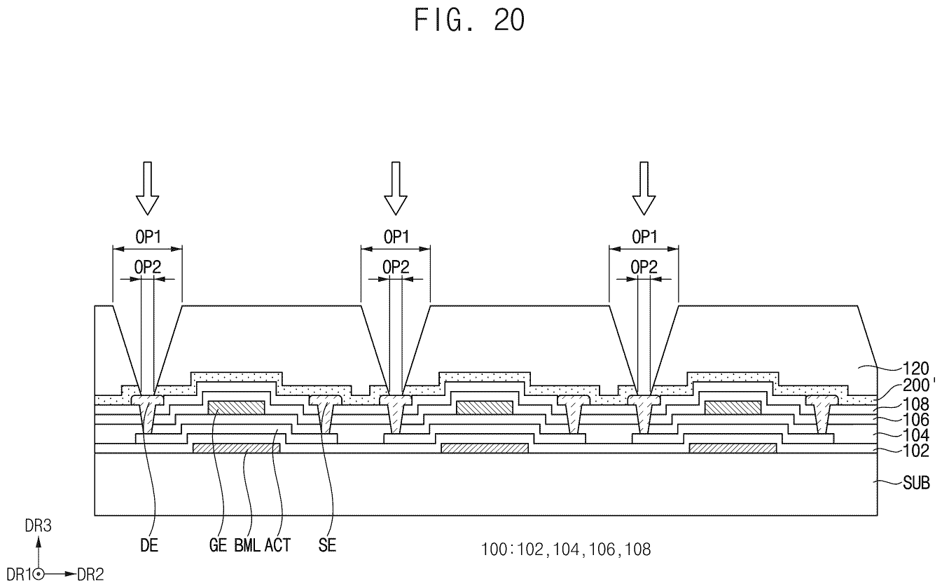

Referring to FIG. 20, a portion of the hydrogen supply layer 200a′ may be removed through an etching process. Accordingly, a hydrogen supply layer 200a′ in which the second opening OP2 is defined may be formed. The second opening OP2 may overlap the first opening OP1 in a plan view. A width of the first opening OP1 may be greater than a width of the second opening OP2. A portion of the drain electrode DE may be exposed through the first and second openings OP1 and OP2. In another embodiment, a portion of the source electrode SE may be exposed through the first and second openings OP1 and OP2.

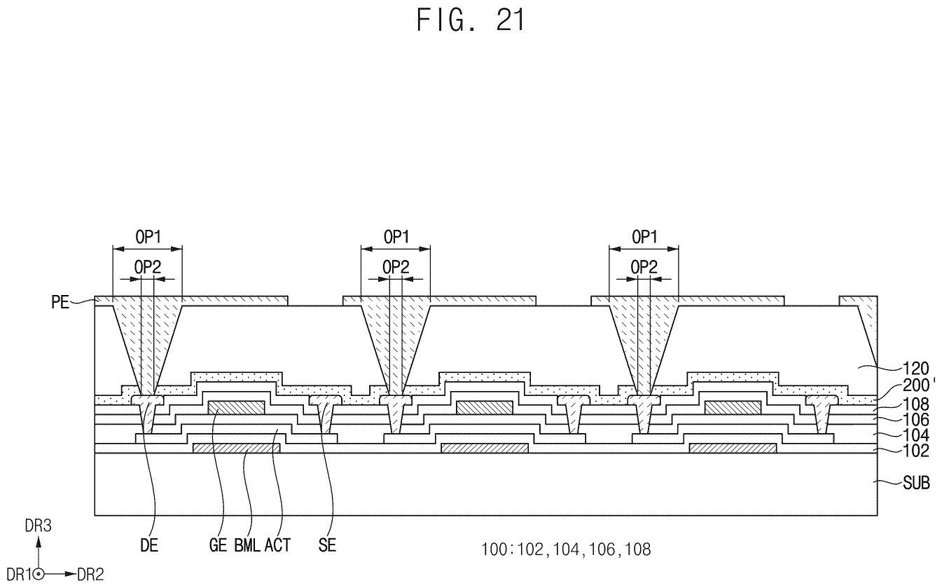

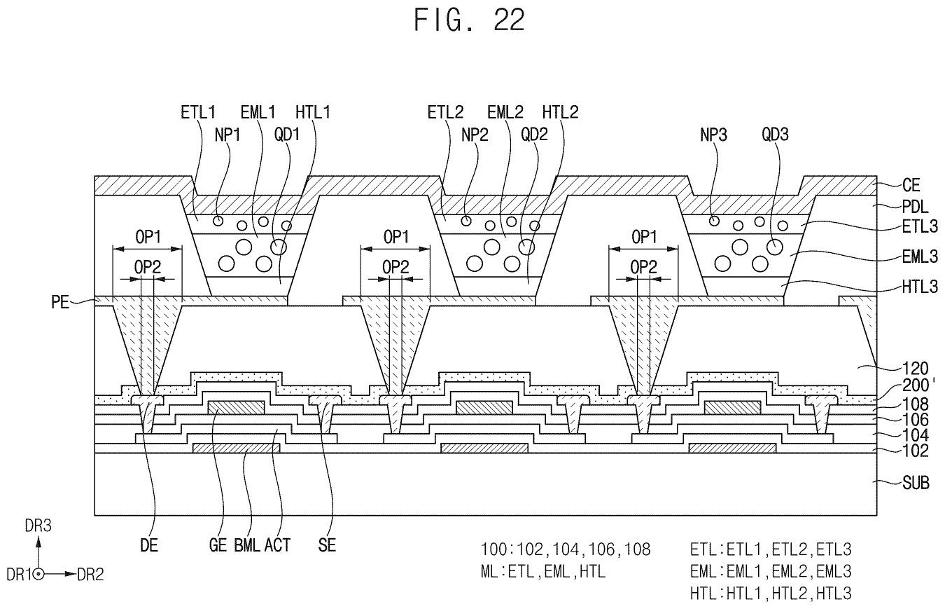

Referring to FIGS. 21 and 22, the pixel electrode PE may be formed on the organic insulating layer 120. The pixel electrode PE may contact each of an upper and a side surface of the organic insulating layer 120. The pixel electrode PE may contact the hydrogen supply layer 200′ through the first opening OP1. The pixel electrode PE may contact a portion of the drain electrode DE through the second opening OP2. In another embodiment, the pixel electrode PE may contact a portion of the source electrode SE through the second opening OP2.

The hole auxiliary layer HTL, the light-emitting layer EML, the electron auxiliary layer ETL, the pixel defining layer PDL, and the common electrode CE may be formed on the pixel electrode PE. The encapsulation layer (e.g., the encapsulation layer TFE in FIG. 15) may be formed on the common electrode CE. Accordingly, the display device DD in FIG. 1 including the structure of FIG. 15 may be manufactured.

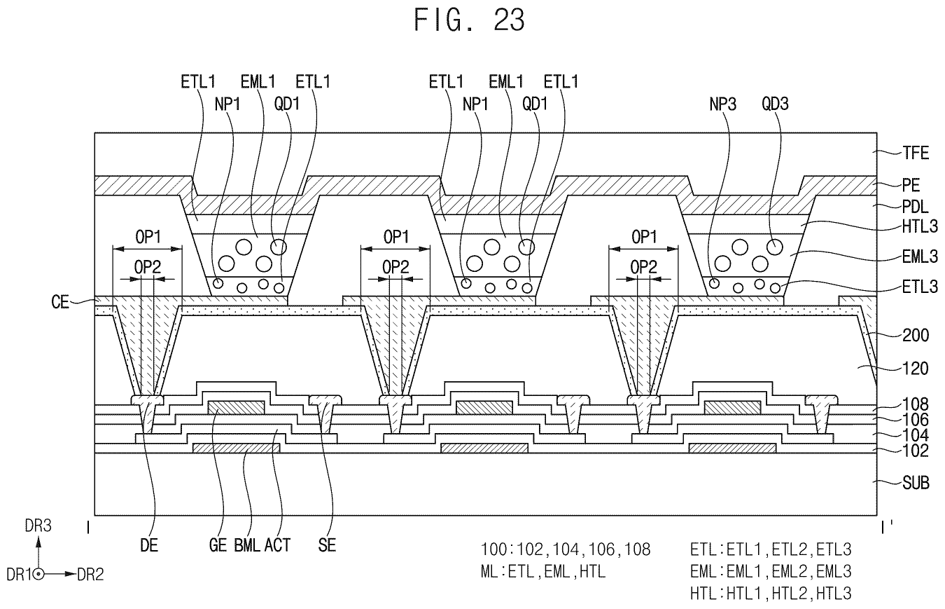

FIG. 23 is a schematic cross-sectional view illustrating an embodiment of the display device in FIG. 1 taken along line I-I′.

The display device DD described with reference to FIG. 23 is substantially the same as the display device DD of FIG. 3 except for an electron auxiliary layer ETL and a hole auxiliary layer HTL. Hereinafter, descriptions that overlap with those described with reference to FIG. 3 will be omitted or simplified.

Referring to FIG. 23, an electron auxiliary layer ETL may be disposed on the pixel electrode PE. The light-emitting layer EML may be disposed on the electron auxiliary layer ETL. A hole auxiliary layer HTL may be disposed on the light-emitting layer EML. In other words, the hole auxiliary layer HTL may be disposed on an upper portion of the electron auxiliary layer ETL. A distance between the hydrogen supply layer 200 and the electron auxiliary layer ETL in FIG. 23 may be closer than a distance in FIG. 3. Accordingly, a hydrogen ion in the hydrogen supply layer 200 may more readily diffuse into a metal material included in the electron auxiliary layer ETL.

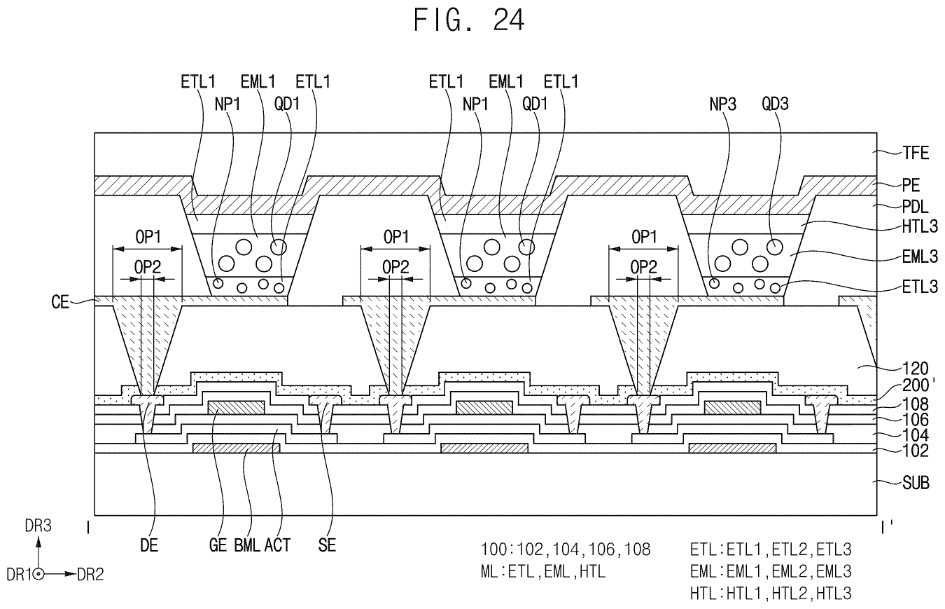

FIG. 24 is a schematic cross-sectional view illustrating an embodiment of the display device in FIG. 1 taken along line I-I′.

The display device DD described with reference to FIG. 24 is substantially the same as the display device DD of FIG. 15 except for an electron auxiliary layer ETL and a hole auxiliary layer HTL. Hereinafter, descriptions that overlap with those described with reference to FIG. 15 will be omitted or simplified.

Referring to FIG. 24, an electron auxiliary layer ETL may be disposed on the pixel electrode PE. The light-emitting layer EML may be disposed on the electron auxiliary layer ETL. A hole auxiliary layer HTL may be disposed on the light-emitting layer EML. In other words, the hole auxiliary layer HTL may be disposed on an upper portion of the electron auxiliary layer ETL. A distance between the hydrogen supply layer 200′ and the electron auxiliary layer ETL in FIG. 24 may be closer than a distance in FIG. 15. Accordingly, a hydrogen ion in the hydrogen supply layer 200′ may more readily diffuse into a metal material included in the electron auxiliary layer ETL.

The display device and the method of manufacturing the same according to the embodiments may be applied to a display device included in a computer, a notebook, a mobile phone, a smartphone, a smart pad, a PMP, a PDA, an MP3 player, or the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
an inorganic insulating layer disposed on a substrate;
a hydrogen supply layer disposed on the inorganic insulating layer;
a pixel electrode contacting the hydrogen supply layer; and
an interlayer that receives a hydrogen ion from the hydrogen supply layer and is disposed on the pixel electrode.

2. The display device of claim 1, further comprising:
an organic insulating layer disposed on the inorganic insulating layer,
wherein the hydrogen supply layer is disposed on the organic insulating layer.

3. The display device of claim 2, wherein an upper surface of the hydrogen supply layer contacts the pixel electrode.

4. The display device of claim 2, wherein the hydrogen supply layer covers an upper surface of the organic insulating layer and a side surface of the organic insulating layer.

5. The display device of claim 2, wherein
the organic insulating layer includes a first opening penetrating the organic insulating layer, and
the hydrogen supply layer includes a second opening overlapping a first opening in a plan view.

6. The display device of claim 5, wherein the hydrogen supply layer covers the organic insulating layer in the first opening.

7. The display device of claim 1, further comprising:
an organic insulating layer disposed on the inorganic insulating layer,
wherein the hydrogen supply layer is disposed between the inorganic insulating layer and the organic insulating layer.

8. The display device of claim 7, wherein the hydrogen supply layer contacts each of the inorganic insulating layer and the organic insulating layer.

9. The display device of claim 7, wherein
the organic insulating layer includes a first opening, and
the hydrogen supply layer includes a second opening overlapping a first opening in a plan view.

10. The display device of claim 9, wherein a portion of the hydrogen supply layer contacts the pixel electrode through the first opening.

11. The display device of claim 1, further comprising:
a common electrode disposed on the interlayer,
wherein the interlayer includes a light-emitting layer and an electron auxiliary layer that supplies an electron to the light-emitting layer.

12. The display device of claim 11, wherein
the light-emitting layer includes a quantum dot, and
the electron auxiliary layer includes a metal oxide.

13. The display device of claim 12, the electron auxiliary layer includes at least one of a zinc oxide and a zinc manganese oxide.

14. The display device of claim 1, wherein the hydrogen supply layer includes a silicon nitride.

15. The display device of claim 1, wherein the hydrogen supply layer includes a silicon oxide.

16. The display device of claim 1, wherein the hydrogen supply layer includes an amorphous silicon.

17. A method of manufacturing a display device, the method comprising:
forming an inorganic insulating layer on a substrate;
forming a hydrogen supply layer on the inorganic insulating layer;
forming a pixel electrode contacting the hydrogen supply layer on the hydrogen supply layer; and
forming an interlayer that receives a hydrogen ion from the hydrogen supply layer on the pixel electrode.

18. The method of claim 17, further comprising:
forming a preliminary organic insulating layer on the inorganic insulating layer;
forming an organic insulating layer including a first opening by etching a portion of the preliminary organic insulating layer;
forming a preliminary hydrogen supply layer covering the organic insulating layer in the first opening on the organic insulating layer; and
forming the hydrogen supply layer including a second opening corresponding to the first opening by etching a portion of the preliminary hydrogen supply layer.

19. The method of claim 17, further comprising:
forming a preliminary hydrogen supply layer on the inorganic insulating layer;
forming a preliminary organic insulating layer on the preliminary hydrogen supply layer;
forming an organic insulating layer including a first opening by etching a portion of the preliminary organic insulating layer; and
forming the hydrogen supply layer including a second opening corresponding to the first opening by etching a portion of the preliminary hydrogen supply layer.

20. The method of claim 17, further comprising:
Performing a hydrogen plasma treatment on at least a portion of the hydrogen supply layer, before the forming of the pixel electrode.
